(19) United States
(12) Patent Application Publication
(10) Pub. No.: US 2004/0229440 A1
(43) Pub. Date: Nov. 18, 2004

(54) Micro-actuator, variable optical attenuator provided with micro-actuator and method for manufacturing the same

(76) Inventors: Jong Sam Kim, Suwon (KR); Jung Hyun Lee, Suwon (KR); Yoon Shik Hong, Sungnam (KR)

Correspondence Address: LOWE HAUPTMAN GILMAN AND BERNER, LLP, 1700 DIAGONAL ROAD, SUITE 300 /310, ALEXANDRIA, VA, 22314, US

(21) Appl. No.: 10/606,378

(22) Filed: Jun. 26, 2003

(30) Foreign Application Priority Data
May 15, 2003 (KR) 2003-30927

(51) Int. Cl. H01L 21/338

(52) U.S. Cl. 438/400

(57) ABSTRACT

Disclosed are a micro-actuator for improving driving force in proportion to voltage, a variable optical attenuator provided with the micro-actuator, and a method for manufacturing the same. The MEMS variable optical attenuator comprises a movable electrode arranged on a substrate and provided with a first comb portion moving in a vertical direction of the optical axes, fixed electrodes fixed to the substrate and provided with a second comb portion interdigitated with the first comb portion, and a dielectric material film with permittivity of more than 3 formed on facing side surfaces of teeth of at least one of the first and second comb portions. The variable optical attenuator increases electrostatic capacitance between the comb portions of the movable and fixed electrodes, thus improving driving force in proportion to voltage.

### BACKGROUND OF THE INVENTION

1. Field of the Invention

The present invention relates to a micro electro mechanical system (MEMS), and more particularly to a MEMS optical attenuator, which has higher driving force at constant driving voltage using an additional dielectric material film.

2. Description of the Related Art

Generally, micro-actuators are MEMS structures, which are manufactured by a semiconductor thin film manufacturing technique, thus driving a micro-structure such as an optical element or a magnetic disk so as to provide a designated movement.

Such a micro-actuator comprises a fixed electrode and a movable electrode, which face each other on a silicon substrate. The fixed electrode and the movable electrode are interdigitated with each other, thus forming an interdigitated comb structure. A comb portion of the fixed electrode is fixed on the silicon substrate, while a comb portion of the movable, electrode is floated from the silicon substrate and supported by an elastic body such as a spring. When a designated driving voltage is applied to the micro-actuator, the comb portion of the movable electrode moves toward the comb portion of the fixed electrode by electrostatic capacitance generated between driving electrodes of the fixed electrode and the movable electrode.

There is provided a variable optical attenuator (VOA) as a typical component applying the above-described micro-actuator. The variable optical attenuator is an optical component for changing the amount of light moving from an optical transmitting terminal to an optical receiving terminal. Here, the micro-actuator serves to arrange an optical cut-off film connected to the movable electrode at a desired position between the optical transmitting terminal and the optical receiving terminal according to the applied voltage.

FIG. 1 is a perspective view of a conventional MEMS variable optical attenuator provided with a micro-actuator.

With reference to FIG. 1, the MEMS variable optical attenuator 50 comprises a substrate 10 on which an optical transmitting terminal 15a and an optical receiving terminal 15b are arranged, a micro-actuator including fixed electrodes 20a and 20b and a movable electrode 30, and an optical cut-off film 40 connected to the movable electrode 30. The movable electrode 30 includes a first comb portion 31, a ground electrode 35 fixed to the substrate 10, and an elastic body 37 for connecting the first comb portion 31 and the ground electrode 35. Each of the fixed electrodes 20a and 20b comprises a second comb portion 21a or 21b, and a driving electrode 25a or 25b electrically connected to the second comb portion 21a or 21b. The first comb portion 31 and the second comb portions 21a and 21b are arranged so that the first comb portion 31 is interdigitated with the second comb portions 21a and 21b.

In this variable optical attenuator 50, the first comb portion 31 and the second comb portions 21a and 21b are spaced from each other by a designated distance under the condition that an electrical control signal is not inputted into the driving electrodes 25a and 25b. On the other hand, when the electrical control signal is inputted into the driving electrodes 25a and 25b, electric potential difference occurs between the fixed electrodes 20a and 20b and the movable electrode 30, and electrostatic force is generated between the first comb portion 31 and the second comb portions 21a and 21b.

FIGS. 2a and 2b are schematic plan views illustrating the operation of the conventional micro-actuator using the above-described principle. As shown in FIG. 2a, in the condition that voltage is not applied to the micro-actuator, a first comb portion 81 and a second comb portion 71 are spaced from each other by a designated distance. Then, as shown in FIG. 2b, in the condition that voltage is applied to the micro-actuator, the first comb portion 81 moves closer to the second comb portion 71 by a designated distance (δ) by the electrostatic force generated by the applied voltage. When an electrical signal is removed or the voltage is lowered, the first comb portion 81 returns to its original position by the elastic force of an elastic body (not shown) connected the first comb portion 81. An optical cut-off film 90 connected to the first comb portion 81 is moved to a desired attenuation position according to the driving voltage corresponding to the electrical control signal.

In case that designated driving voltage is inputted to the micro-actuator, when the electrostatic force generated between the first comb portion 81 and the second comb portion 71, that is, the driving force of the first comb portion 81, is increased, the response speed of the micro-actuator is increased and the micro-actuator is operated at low driving voltage. Further, it is possible to allow this low power variable optical attenuator to be applied to a simple control circuit.

For this reason, the distance between the first comb portion and the second comb portion is conventionally narrowed. However, in case that the distance between the first comb portion 81 and the second comb portion 71 is narrowed, there is the occurrence of torsion at ends of the teeth of the comb portions 81 and 71 as shown in FIG. 2b, thus causing the undesired occurrence of short circuits between the neighboring teeth of the first and second comb portions 81 and 71. Consequently, since a method for reducing the distance between the teeth of the comb structure should be designed so that the occurrence of short circuits between the neighboring teeth is prevented, it is difficult to use this method as an effective solution for improving the driving force.

Accordingly, in the art, there is required a novel MEMS variable optical attenuator, which prevents the undesired occurrence of short circuits as well as improves the driving force of the micro-actuator in proportion to voltage.

### SUMMARY OF THE INVENTION

Therefore, the present invention has been made in view of the above problems, and it is an object of the present invention to provide a MEMS variable optical attenuator, in which a dielectric material film is formed on facing side surfaces between teeth of comb-type electrodes of a micro-actuator actuator so as to improve driving force, and a method for manufacturing the MEMS variable optical attenuator.

It is another object of the present invention to provide a micro-actuator, in which a dielectric material film is on facing side surfaces between teeth of interdigitated comb-type electrodes.

In accordance with one aspect of the present invention, the above and other objects can be accomplished by the provision of a MEMS variable optical attenuator for attenuating the amount of light to a designated value by means of an electrical control signal, comprising: a substrate with a flat upper surface; an optical transmitting terminal and an optical receiving terminal, arranged on the upper surface of the substrate so that their optical axes coincide with each other; a movable electrode arranged on the substrate and provided with a first comb portion moving in a vertical direction of the optical axes; fixed electrodes fixed to the substrate and provided with a second comb portion interdigitated with the first comb portion; and an optical cut-off film electrically connected to the first comb portion and being movable to a designated attenuation position between the optical transmitting and receiving terminals according to the movement of the first comb portion, wherein a dielectric material film with permittivity of more than 3 is formed on facing side surfaces of teeth of at least one of the first and second comb portions.

Preferably, the dielectric material film may be formed on facing side surfaces of teeth of both of the first and second comb portions.

Further, preferably, the dielectric material film may be made of a material having step coverage of more than approximately 60%, and selected from the group consisting of SiO₂, Si₃N₄, Ta₂O₅, TiO₂, and TaON.

Moreover, preferably, the dielectric material film may have a thickness sufficient to insulate a voltage corresponding to the electrical control signal. More preferably, the dielectric material film may have a thickness of at least approximately 10 mm so as to assure a sufficient insulating property. Most preferably, under the consideration of the desired step coverage and the permittivity, the dielectric material film may be a Ta₂O₅ film with a thickness of at least approximately 10 mm.

Preferably, the movable electrode may include the first comb portion, a ground electrode fixed on the substrate, and an elastic body for electrically connecting the first comb portion and the ground electrode, and the fixed electrode may include the second comb portion, and driving electrodes electrically connected to the second comb portion for receiving the electrical control signal.

In accordance with another aspect of the present invention, there is provided a method for manufacturing a MEMS variable optical attenuator comprising the steps of: (a) preparing an SOI substrate including upper and lower silicon layers and an insulating layer interposed therebetween; (b) forming a micro-structure by selectively etching the upper silicon layer, the micro-structure including a movable electrode provided with a first comb portion, an optical cut-off film electrically connected to the first comb portion, and fixed electrodes provided with a second comb portion interdigitated with the first comb portion; (c) removing a lower surface of a portion of the micro-structure corresponding to at least the optical cut-off film and the first comb portion; (d) coating a metal film on the surface of a portion of the micro-structure corresponding to at least the movable electrode and the fixed electrodes, thus forming the movable electrode and the fixed electrodes; and (e) forming a dielectric material film on facing side surfaces of teeth of at least one of the first and second comb portions.

Preferably, the step (e) may include (e-1) forming the dielectric material film on upper and side surfaces of the micro-structure; and (e-2) removing the dielectric material film from the upper surface of the micro-structure.

In accordance with yet another aspect of the present invention, there is provided a micro-actuator comprising a movable electrode provided with a first comb portion and fixed electrodes provided with a second comb portion interdigitated with the first comb portion, wherein a dielectric material film with permittivity of more than 3 is formed on facing side surfaces of teeth of at least one of the, first and second comb portions.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a perspective view of a conventional MEMS variable. optical attenuator;

FIGS. 2a and 2b are schematic plan views illustrating the operation of a conventional micro-actuator;

FIG. 3 is a perspective view of a MEMS variable optical attenuator in accordance with the present invention;

FIG. 4a is a cross-sectional view of a micro-actuator in accordance with the present invention;

FIG. 4b is an equivalent circuit diagram of the micro-actuator actuator in accordance with the present invention; and

FIGS. 5a to 5f are cross-sectional views illustrating a method for manufacturing a MEMS variable optical attenuator in accordance with the present invention.

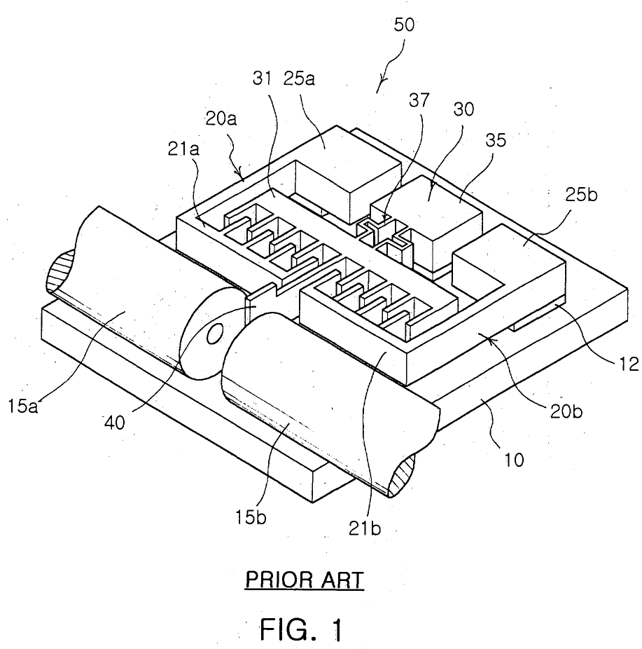

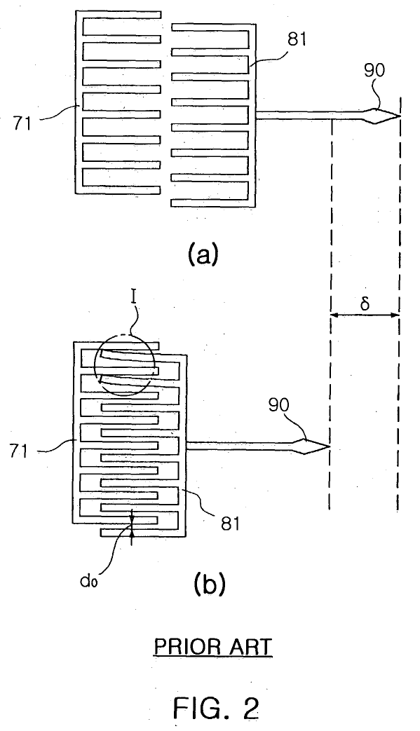

### DESCRIPTION OF THE PREFERRED EMBODIMENTS

Now, preferred embodiments of the present invention will be described in detail with reference to the annexed drawings.

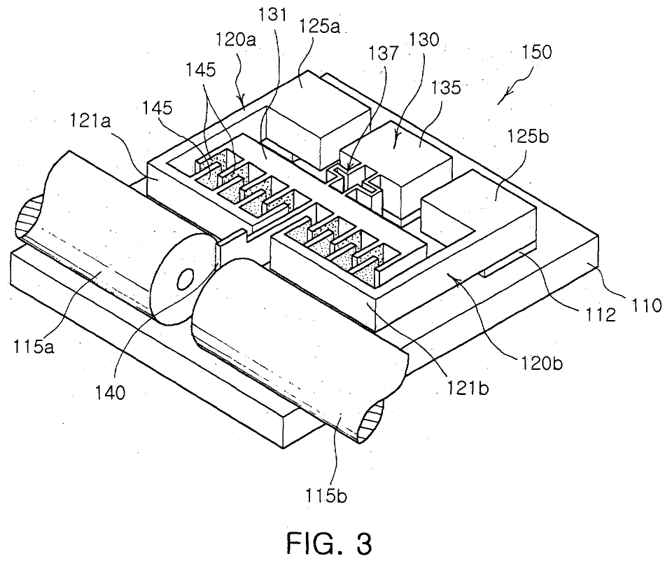

FIG. 3 is a perspective view of a MEMS variable optical attenuator in accordance with the present invention.

With reference to FIG. 3, the MEMS variable optical attenuator 100 comprises a substrate 110 on which an optical transmitting terminal 115a and an optical receiving terminal 115b are arranged, a micro-actuator including fixed electrodes 120a and 120b and a movable electrode 130, and an optical cut-off film 140 connected to the movable electrode 130.

The movable electrode 130 includes a first comb portion 131, a ground electrode 315 fixed to the substrate 110, and an elastic body 137 for connecting the first comb portion 131 and the ground electrode 135. Each of the fixed electrodes 120a and 120b comprises a second comb portion 121a or 121b, and a driving electrode 125a or 125b electrically connected to the second comb portion 121a or 121b. The first comb portion 131 and the second comb portions 121a and 121b are arranged so that the first comb portion 131 is interdigitated with the second comb portions 121a and 121b.

This micro-actuator is made of a material such as silicon the same as the material of the substrate 110. The micro-actuator is not limited to the above-described structure, but those skilled in the art will appreciate that it may be modified to have various structures.

In this embodiment, a dielectric material film 145 is formed on facing side surfaces of the first comb portion 131 and the second comb portions 121a and 121b. The present inventor(s) notes that the driving force acting between the first comb portion 131 and the second comb portions 121a and 121b is increased by raising permittivity between the first comb portion 131 and the second comb portions 121a and 121b, because the driving force depends on electrostatic capacitance generated between the first comb portion 131 and the second comb portions 121a and 121b.

Based on the above principle, the dielectric material film 145 with relatively high permittivity is formed on the side surfaces of the first comb portion 131 and the second comb portions 121a and 121b, which face each other. The dielectric material film 1450 has electrostatic capacitance higher than that of air between the side surfaces of the first comb portion 131 and the second comb portions 121a and 121b. The dielectric material film 145 may be formed on the side surfaces of both the first comb portion 131 and the second comb portions 121a and 121b, or selectively formed on the side surfaces of either the first comb portion 131 or the second comb portions 121a and 121b.

Preferably, the dielectric material film 145 is made of a material with permittivity sufficient to increase the electrostatic capacitance. Further, since the dielectric material film 145 should be formed between the first comb portion 131 and the second comb portions 121a and 121b, i.e., on the facing side surfaces of the first comb portion 131 and the second comb portions 121a and 121b, it is important to properly deposit the dielectric material on the side surfaces of the first comb portion 131 and the second comb portions 121a and 121b. Accordingly, it is preferable to use a material with excellent step coverage.

Hereinafter, Table 1 shows evaluated results of dielectric materials according to preferable characteristics.

| Dielectric | | Step coverage | |
|---|---|---|---|
| material | Permittivity | evaluation | Result |
| SiO₂ | 3.9 | ◯ | ◯ |
| Si₃N₄ | 6˜7 | ◯ | ◯ |
| Ta₂O₅ | 25 | ◯ | ◯ |
| TiO₂ | 34 | ◯ | ◯ |
| TaON | 30˜40 | ◯ | ◯ |
| Ba(Zr, Ti)O₃ | 145 | X | X |
| (Ba, Sr)TiO₃ | >200 | X | X |
| PLZT | >900 | X | X |
| Al₂O₃ | 9.34 | X | X |

In Table 1, the step coverage(%) of each material was calculated by an equation, as follows.

$$StepCoverage ( \% ) = \frac{ThicknessofFilmDepositedonLowerPortionofSideSurface}{ThicknessofFilmDepositedonUpperSurface} \times 100$$

The step coverage was evaluated to be excellent (O) only when the calculated value is more than 60%. Since it is important to form the dielectric material film on the side surfaces of the comb portions of the electrodes, the step coverage property may be an essential evaluation factor. Further, as described above, the material used as the dielectric film material preferably has permittivity of more than approximately 3.

As a result, as shown in Table 1, it is preferable to use SiO₂, Si₃N₄, Ta₂O₅, TiO₂, or TaON as the dielectric material film, and it is more preferable to use Ta₂O₅, TiO₂, or TaON so as to assure excellent step coverage and higher permittivity.

Since the dielectric material film used in the present invention has an insulating property, even if torsion at ends of the teeth occurs due to the high driving force, the undesired occurrence of short circuits between the electrodes is prevented. For this reason, preferably, the dielectric material film is formed to have a proper thickness so that the dielectric material film has sufficient insulating property to the driving voltage. In case that one material selected from the above-enumerated dielectric materials is used to form the dielectric material film, the dielectric material film has a thickness of at least 10 mm so that the undesired occurrence of short circuits is prevented.

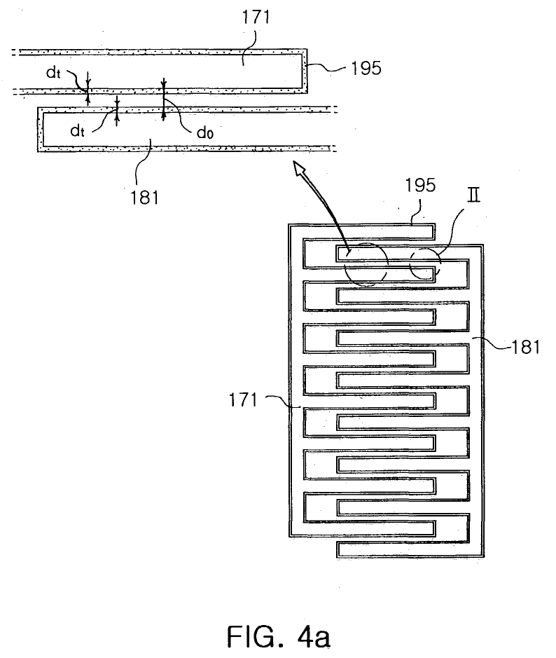

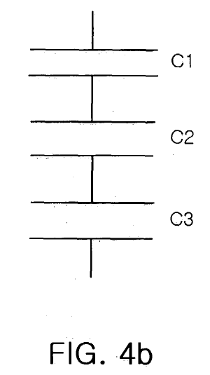

Hereinafter, the increase of the driving force between the first comb portion of the movable electrode and the second comb portion of the fixed electrode is described in detail with reference to FIGS. 4a and 4b.

FIG. 4a is a cross-sectional view of a micro-actuator in accordance with the present invention. FIG. 4b is an equivalent circuit diagram of the micro-actuator illustrating electrostatic capacitance generated between neighboring electrode fingers of the two comb portions.

With reference to FIG. 4a, each of a first comb portion 181 of a movable electrode and a second comb portion, 171 of a fixed electrode comprises a dielectric material film 195 formed on the facing side surfaces of their fingers. The dielectric material film 195 formed one side surface of the first comb portion 181 and the dielectric material film 195 formed the facing side surface of the second comb portion 171 are spaced from each other by a designated distance (d₀). The dielectric material film 195 is a Ta₂O₅film with a designated thickness (dₜ)

In order to check the increase of driving force between the comb portions provided with the dielectric material film, FIG. 4b shows an equivalent circuit diagram illustrating electrostatic capacitance generated between both electrode fingers, represented by a portion “II” of FIG. 4a.

In the equivalent circuit diagram of the portion “II” of FIG. 4a, as shown in FIG. 4b, three electrostatic capacitances (C₁, C₂, and C₃) are connected in series. Two electrostatic capacitances (C₁ and C₃) are respectively generated from the two electric material films 195 formed on the side surfaces of the first comb portion 181 and the second comb portion 171, and one electrostatic capacitance (C₂) is generated from a gap (air) therebetween. The electrostatic capacitance of Ta₂O₅ is 25. Accordingly, the electrostatic capacitances (C₁, C₂, and C₃) are represented by equations, as follows.

$$\begin{matrix}{C}_{1} = {C}_{3} = {K}_{{Ta}_{2} {O}_{5}} \frac{{ϵ}_{0}^{A}}{{d}_{t}} = 25 {K}_{Air} \frac{{ϵ}_{0}^{A}}{{d}_{t}} \\ {C}_{2} = {K}_{Air} \frac{{ϵ}_{0}^{A}}{{d}_{0} - 2 {d}_{t}}\end{matrix}$$

Here, ε represents permittivity in the vacuum condition, A represents the dimensions of a corresponding area, and K_{Air} and K_{Ta205} respectively represent dielectric constants of air and Ta₂O₅.

Accordingly, the total electrostatic capacitance (C_{T}) is represented by an equation, as follows.

$${C}_{T} = \frac{25 {K}_{Air} {ϵ}_{0}^{A}}{25 {d}_{0} - 48 {d}_{t}}$$

Here, the thickness (dₜ) of the dielectric material film 195 is not less than 0 and not more than d₀/2. An electrostatic capacitance (C₀) between electrode fingers without the dielectric material film 195, spaced from each other by the same distance, is represented by an equation, as follows.

$${C}_{0} = \frac{{K}_{Air} {ϵ}_{0}^{A}}{{d}_{0}}$$

Accordingly, the range of the total electrostatic capacitance (C_{T}) generated in the micro-actuator of the present invention is defined to be 0<C_{T}<25C₀.

The driving force (F) of the micro-actuator is represented by an equation, as follows.

$$F = \frac{{N}_{c}^{tC}}{{V}^{2}}$$

Here, N_{c} represents the number of electrode fingers of the comb portions, and t represents the thickness of the electrode finger. C represents the electrostatic capacitance, and V represents the driving voltage.

When the number and width of the teeth (or, the electrode fingers) and the driving force are the same as those of the conventional micro-actuator, the micro-actuator of the present invention increases its driving force up to nearly 25 times by means of the dielectric material film.

For example, in case the distance between the neighboring electrode fingers of the two comb portions is 3 μm and the thickness of the dielectric material film formed on the side surfaces of the electrode finger is 0.5 μm, the total electrostatic capacitance of the micro-actuator of the present invention is increased three times as much as the total capacitance of the conventional micro-actuator.

As described above, the micro-actuator of the present invention has higher driving force at the same driving voltage, thus increasing its response speed. Further, the micro-actuator of the present invention uses lower driving voltage so as to provide the same capacity as that of the conventional micro-actuator, thus reducing the power consumption and simplifying the constitution of a control circuit.

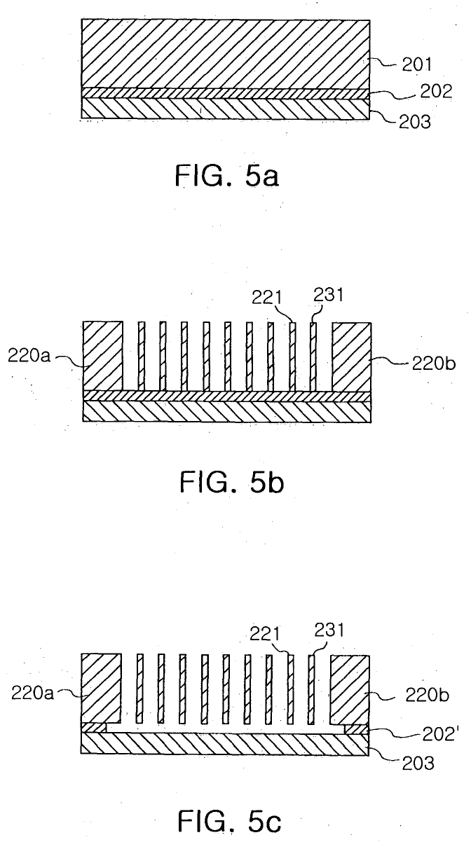

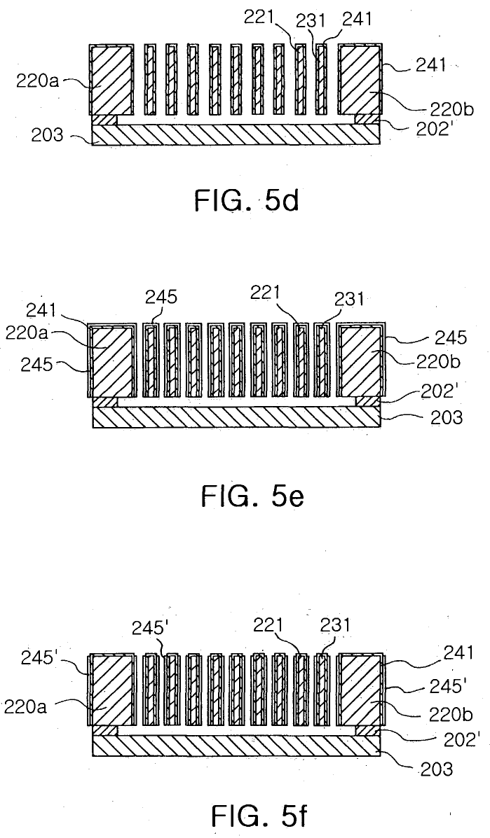

FIGS. 5a to 5f are cross-sectional views illustrating a method for manufacturing a MEMS variable optical attenuator in accordance with the present invention. These drawings show comb-type portions of fixed and variable portions provided with dielectric material films in accordance with the present invention.

As shown in FIG. 5a, there is prepared a SOI substrate including upper and lower silicon layers 201 and 203 and an insulating layer 202 interposed therebetween. Generally, a SiO₂ layer is used as the insulating layer 202.

As shown in FIG. 5b, the upper silicon layer 201 is selectively etched, thereby forming a micro-structure required in the variable optical attenuator shown in FIG. 3. Such a micro-structure includes a movable electrode (not shown) provided with a first comb portion 221, an optical cut-off film (not shown) connected to the first comb portion 221, and fixed electrodes 220a and 220b provided with a second comb portion 221 interdigitated with the first comb portion 221. The selective etching of the upper silicon layer 201 is achieved by photolithography.

As shown in FIG. 5c, at least a portion of the insulating layer 202, which is disposed under the optical cut-off film and the first comb portion 221 of the micro-structure, is removed. Since the optical cut-off film and the first comb portion 221 are formed to have a movable structure, the corresponding portion of the insulating layer 202 is removed so that the optical cut-off film and the first comb portion 221 are not fixed to the lower silicon layer 203. As shown in FIG. 5c, the second comb portion 231 is disposed close to the first comb portion 221, thus allowing another portion of the insulating layer 202 disposed under the second comb portion 231 to be also removed for convenience of a process. However, the other portions of the fixed electrodes 220a and 220b connected to the second comb portion 231, for example, driving electrodes, are fixed to the lower silicon layer 203 by means of a remaining oxide layer 202 together with a ground electrode of the movable electrode.

As shown in FIG. 5d, a metal film 241 is coated on portions of the micro-structure corresponding to at least the movable electrode and the fixed electrodes 220a and 220b, thereby allowing the movable electrode and the fixed electrodes 220a and 220b to be formed. Although FIG. 5d shows only portions of the micro-structure corresponding to the first comb portion 231 and the fixed electrodes 220a and 220b provided with the second comb portion 221, other portions of the movable electrode and the fixed electrodes 220a and 220b are coated with the metal film 241 so that the movable electrode and the fixed electrodes 220a and 220b have electric conductivity.

Finally, a dielectric material film 245 is formed on facing side surfaces of teeth of at least one of the first and second comb portions 231 and 221. In this embodiment, the dielectric material 245′ film is formed on facing side surfaces of teeth of both of the first and second comb portions 231 and 221, but is not limited thereto. This step for forming the dielectric material film 245′ may be achieved by selectively depositing a dielectric material only on the first and the second comb portions 231 and 221, which require the dielectric material film 245′ Alternatively, as shown in FIGS. 5e and 5f, the step for forming the dielectric material film 245′ may be achieved by depositing a dielectric material 245 on the total area of the micro-structure, i.e., the upper and side surfaces of the movable electrode and the fixed electrodes 220a and 220b and then removing the dielectric material 245 deposited on the upper surfaces so that the dielectric material film 245′ remains only on the side surfaces. Here, the step for removing the dielectric material 245 deposited on the upper surfaces may be easily achieved by an over-etching method being obvious to those skilled in the art. By this simple process, the dielectric material film 245′ remains on the side surfaces of the teeth of the first and second com portions 231 and 221, and the metal film 241 formed on the upper surfaces of the driving electrodes of the fixed electrode 220a and 220b and a ground electrode (not shown) of the movable electrode is exposed to the outside so that the metal film 241 is electrically connected to an external circuit. Accordingly, in the steps shown in FIGS. 5e and 5f, the objects of the present invention can be simply achieved without the introduction of a complicated process for selectively depositing the dielectric material such as photolithography.

As apparent from the above description, the present invention provides a variable optical attenuator, in which a dielectric material film with designated permittivity is deposited on facing side surfaces of teeth of comb portions of movable and fixed electrodes, thus increasing electrostatic capacitance and improving driving force in proportion to voltage. Accordingly, it is possible to improve response speed of the variable optical attenuator to a control signal and to reduce the power consumption of the attenuator, thus simplifying a control circuit of the variable optical attenuator. The variable optical attenuator of the present invention provides a further advantage in preventing the undesired occurrence of short circuits between the neighboring teeth of the comb portions due to torsion generated at ends of the teeth.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A MEMS variable optical attenuator for attenuating the amount of light to a designated value by means of an electrical control signal, comprising:
a substrate with a flat upper surface;
an optical transmitting terminal and an optical receiving terminal, arranged on the upper surface of the substrate so that their optical axes coincide with each other;
a movable electrode arranged on the substrate and provided with a first comb portion moving in a vertical direction of the optical axes;
fixed electrodes fixed to the substrate and provided with a second comb portion interdigitated with the first comb portion; and
an optical cut-off film electrically connected to the first comb portion and being movable to a designated attenuation position between the optical transmitting and receiving terminals according to the movement of the first comb portion,
wherein a dielectric material film with permittivity of more than 3 is formed on facing side surfaces of teeth of at least one of the first and second comb portions.

2. The MEMS variable optical attenuator as set forth in claim 1,
wherein the dielectric material film is formed on facing side surfaces of teeth of both of the first and second comb portions.

3. The MEMS variable optical attenuator as set forth in claim 1,
wherein the dielectric material film is made of a material, having step coverage of more than approximately 60%, deposited on the side surfaces.

4. The MEMS variable optical attenuator as set forth in claim 1,
wherein the dielectric material film is made of a material selected from the group, consisting of SiO₂, Si₃N₄, Ta₂O₅, TiO₂, and TaON.

5. The MEMS variable optical attenuator as set forth in claim 1,
wherein the dielectric material film has a thickness sufficient to insulate a voltage corresponding to the electrical control signal.

6. The MEMS variable optical attenuator as set forth in claim 5,
wherein the dielectric material film is a Ta₂O₅ film with a thickness of at least approximately 10 mm.

7. The MEMS variable optical attenuator as set forth in claim 1,
wherein the dielectric material film is a Ta₂O₅ film with a thickness of at least approximately 10 mm.

8. A method for manufacturing a MEMS variable optical attenuator comprising the steps of:
(a) preparing an SOI substrate including upper and lower silicon layers and an insulating layer interposed therebetween;
(b) forming a micro-structure by selectively etching the upper silicon layer, said micro-structure including a movable electrode provided with a first comb portion, an optical cut-off film electrically connected to the first comb portion, and fixed electrodes provided with a second comb portion interdigitated with the first comb portion;
(c) removing a lower surface of a portion of the micro-structure corresponding to at least the optical cut-off film and the first comb portion;
(d) coating a metal film on the surface of a portion of the micro-structure corresponding to at least the movable electrode and the fixed electrodes, thus forming the movable electrode and the fixed electrodes; and
(e) forming a dielectric material film on facing side surfaces of teeth of at least one of the first and second comb portions.

9. The method for manufacturing a MEMS variable optical attenuator as set forth in claim 8,
wherein in the step (e) the dielectric material film is formed on facing side surfaces of teeth of both of the first and second comb portions.

10. The method for manufacturing a MEMS variable optical attenuator as set forth in claim 8,
wherein the dielectric material film is made of a material with permittivity of more than 3.

11. The method for manufacturing a MEMS variable optical attenuator as set forth in claim 8,
wherein the dielectric material film is made of a material, having step coverage of more than approximately 60%, deposited on the side surfaces.

12. The method for manufacturing a MEMS variable optical attenuator as set forth in claim 8,
wherein the dielectric material film is made of a material selected from the group consisting of SiO₂, Si₃N₄, Ta₂O₅, TiO₂, and TaON.

13. The method for manufacturing a MEMS variable optical attenuator as set forth in claim 8,
wherein the dielectric material film has a thickness sufficient to insulate a voltage corresponding to the electrical control signal.

14. The method for manufacturing a MEMS variable optical attenuator as set forth in claim 13,
wherein the dielectric material film has a thickness of at least approximately 10 mm.

15. The method for manufacturing a MEMS variable optical attenuator as set forth in claim 8,
wherein the dielectric material film is made of Ta₂O₅ so as to have a thickness of at least approximately 10 mm.

16. The method for manufacturing a MEMS variable optical attenuator as set forth in claim 8,
wherein the step (e) includes:
(e-1) forming the dielectric material film on upper and side surfaces of the micro-structure; and
(e-2) removing the dielectric material film from the upper surface of the micro-structure.

17. A micro-actuator comprising a movable electrode provided with a first comb portion and fixed electrodes provided with a, second comb portion interdigitated with the first comb portion,
wherein a dielectric material film with permittivity of more than 3 is formed on facing side surfaces of teeth of at least one of the first and second comb portions.
